(19) United States
(12) Patent Application Publication
(10) Pub. No.: US 2016/0006458 A1
(43) Pub. Date: Jan. 7, 2016

(54) DECODING TECHNIQUES FOR LOW-DENSITY PARITY CHECK CODES

(71) Applicant: SANDISK TECHNOLOGIES INC., PLANO, TX (US)

(72) Inventors: ZONGWANG LI, DUBLIN, CA (US); MANUEL ANTONIO D'ABREU, EL DORADO HILLS, CA (US)

(73) Assignee: SANDISK TECHNOLOGIES INC.

(21) Appl. No.: 14/321,069

(22) Filed: Jul. 1, 2014

(51) Int. Cl. H03M 13/11; G11C 29/52; G06F 11/10

(52) U.S. Cl. CPC H03M 13/1108; H03M 13/1111; G06F 11/1016; G06F 11/1072; G11C 29/52

(57) ABSTRACT

A data storage device includes a memory. A method includes initiating a decoding process at the data storage device to decode data sensed from the memory. The method further includes accessing a mapping table to determine a variable node message value during a variable node processing operation of the decoding process.

### FIELD OF THE DISCLOSURE

The present disclosure is generally related to decoders and more particularly to low-density parity check (LDPC) decoders.

### BACKGROUND

Non-volatile data storage devices have enabled increased portability of data and software applications. For example, multi-level cell (MLC) storage elements of a flash memory device may each store multiple bits of data, enhancing data storage density as compared to single-level cell (SLC) flash memory devices. Consequently, flash memory devices enable users to store and access a large amount of data. As a number of bits stored per cell increases, errors in stored data typically increase (e.g., due to noise and other factors). A data storage device may encode and decode data using an error correcting code (ECC) technique to correct data errors.

An example of an ECC technique is a low-density parity check (LDPC) technique. To illustrate, an encoder may multiply user data with an LDPC generator matrix to produce parity bits. During a decoding process, a decoder may use the parity bits to correct one or more errors that may be present in the user data (e.g., due to noise, read or write errors, etc.). For example, the decoder may adjust one or more bit values of the user data and/or the parity bits to cause the user data and the parity bits to satisfy a set of parity equations specified by a parity check matrix. The decoder may operate using “hard” bits that each have either a logic “0” value or a logic “1” value, or the decoder may operate using “soft” bits, each selected from a range of values indicating bit reliability.

To determine which bit values to adjust, the decoder may iteratively update variable nodes and check nodes. The variable nodes may represent bit values, and the check nodes may represent the set of parity equations. The decoder may iteratively adjust values associated with the variable nodes and the check nodes, such as by passing update messages between the variable nodes and the check nodes during the decoding process. The decoding process may terminate when the set of parity equations is satisfied (i.e., when the decoding process converges to a valid ECC codeword) or when a threshold number of iterations is reached without converging to a valid ECC codeword. The messages may be generated using computationally complex operations, which can consume power and processing resources at a device.

### SUMMARY

A decoder may be configured to decode low-density parity check (LDPC) information using a reduced number of input bits (e.g., using only “hard” bits or using hard bits in connection with a reduced number of “soft” bits) while also achieving a high error correction capability. Use of hard bits in a decoding scheme may enable simpler and faster operations as compared to using a large number of soft bits (e.g., by avoiding repetitive sensing operations to generate sets of soft bits). The decoder may therefore have low power consumption and low complexity.

To achieve high error correction capability using a reduced number of input bits, the decoder may utilize a simplified “minimum-sum” (min-sum) LDPC decoding process to decode information using “first minimum” (min1) values and without storing “second minimum” (min2) values. To illustrate, instead of generating and storing a min2 value during check node processing, the decoder may compare a min1 value to a threshold, such as a variable node message value. The decoder may set a flag based on the comparison. The flag may include a single bit indicating a magnitude of the min1 value relative to the threshold, which may reduce complexity of certain decoder operations relative to a conventional check node processing technique that calculates and stores a multi-bit min2 value in addition to a min1 value.

Alternatively or in addition, decoding operations may be simplified using a non-linear technique to select variable node message values. For example, a decoder may access a lookup table to determine variable node messages to simplify variable node processing. Selecting variable node message values from a lookup table may have lower “resolution” (e.g., may result in lower error correction capability and/or lower decoder throughput in some cases) relative to conventional techniques that calculate variable node message values. However, lower error correction capability may be acceptable in some circumstances, such as at a “beginning-of-life” stage of operation of a device (before physical wear occurs at the device). In this case, overall device performance may be improved by permitting decreased error correction capability in order to improve power efficiency and to facilitate faster decoding operations.

### BRIEF DESCRIPTION OF THE DRAWINGS

FIG. 1 is a block diagram of a particular illustrative embodiment of a system including a data storage device that includes a decoder;

FIG. 2 is a block diagram of a particular illustrative embodiment of a device that can be implemented within a decoder, such as the decoder of FIG. 1;

FIG. 3 is a data flow diagram of an example process that can be performed at the decoder of the data storage device of FIG. 1;

FIG. 4 is a data flow diagram of another example process that can be performed at the decoder of the data storage device of FIG. 1;

FIG. 5 is a block diagram of a variable node unit (VNU) processor that may be included in the decoder of the data storage device of FIG. 1;

FIG. 6 is a block diagram of an on-the-fly syndrome value generator that may be included in the decoder of the data storage device of FIG. 1;

FIG. 7 is a flow diagram that illustrates a particular example method of operation of the decoder of the data storage device of FIG. 1;

FIG. 8 is a block diagram of a particular embodiment of a memory that may be included in the data storage device of FIG. 1; and

FIG. 9 is a block diagram of another particular embodiment of a memory that may be included in the data storage device of FIG. 1.

### DETAILED DESCRIPTION

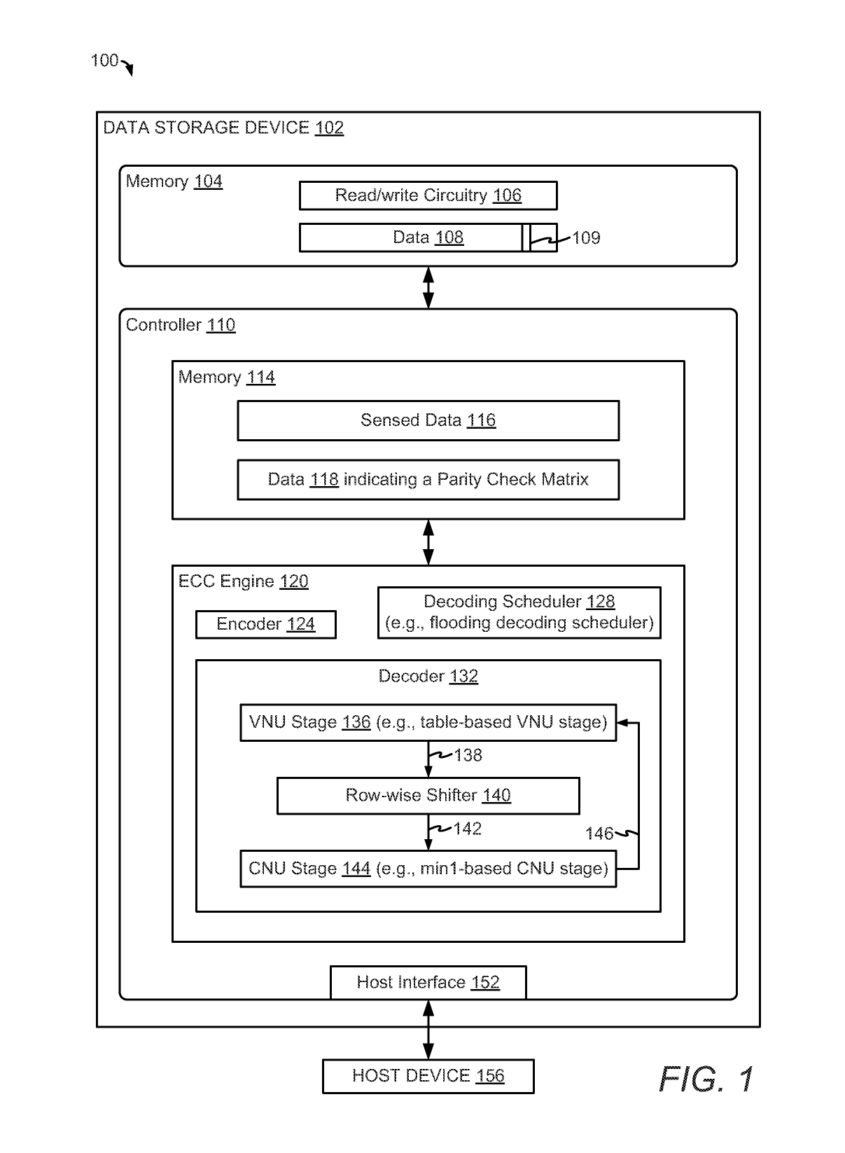

Referring to FIG. 1, a particular illustrative embodiment of a system is depicted and generally designated 100. The system 100 includes a data storage device 102 and a host device 156. The data storage device 102 and the host device 156 may be operationally coupled via a connection, such as a bus or a wireless connection. The data storage device 102 may be embedded within the host device 156, such as in accordance with a Joint Electron Devices Engineering Council (JEDEC) Solid State Technology Association Universal Flash Storage (UFS) configuration. Alternatively, the data storage device 102 may be removable from the host device 156 (i.e., “removably” coupled to the host device 156). As an example, the data storage device 102 may be removably coupled to the host device 156 in accordance with a removable universal serial bus (USB) configuration.

The data storage device 102 may include a memory 104 and a controller 110. The memory 104 may include a non-volatile memory, such as a non-volatile NAND flash memory or a non-volatile resistive random access memory (ReRAM). The memory 104 may have a three-dimensional (3D) memory configuration. Alternatively, the memory 104 may have another configuration, such as a two-dimensional (2D) memory configuration.

The memory 104 may include read/write circuitry 106. In a particular implementation, the memory 104 is a non-volatile memory having a three-dimensional (3D) memory configuration that is monolithically formed in one or more physical levels of arrays of memory cells having an active area disposed above a silicon substrate. The data storage device 102 may include circuitry, such as the read/write circuitry 106, that is associated with operation of the memory cells. The read/write circuitry 106 may be configured to sense data stored at the memory 104 using a “hard” read technique (e.g., to generate a hard bit having either a logical “0” value or a logical “1” value), a “soft” read technique (e.g., to generate a soft bit indicating a reliability of a sensed value), or a combination thereof.

The memory 104 may include one or more physical pages of storage elements (e.g., word lines of storage elements). The physical pages may be included in one or more blocks (e.g., an erase group of word lines) of the memory 104. The memory 104 may include multiple blocks of physical pages. The physical pages may store data, such as data 108. The data 108 may include a representative value 109.

To illustrate, one or more of the physical pages may correspond to a physical page of single-level cell (SLC) storage elements that can be programmed using the read/write circuitry 106 to store threshold voltages indicating bit values of a logical page, such as in connection with a one-bit-per-cell (“×1”) configuration. Alternatively, one or more of the physical pages may correspond to a physical page of multi-level cell (MLC) storage elements that can be programmed using the read/write circuitry 106 to store threshold voltages indicating bit values of multiple logical pages, such as in connection with a two-bit-per-cell (“×2”) configuration or a three-bit-per-cell (“×3”) configuration, as illustrative examples.

The controller 110 may include a memory 114, an error correcting code (ECC) engine 120, and a host interface 152. The memory 114 may include a random access memory (RAM). Alternatively or in addition, the memory 114 may include another type of memory, such as a nonvolatile memory. The ECC engine 120 may include an encoder 124, a decoding scheduler 128 (e.g., a “flooding” decoding scheduler), and a decoder 132. The decoder 132 may include a set of variable node units (VNUs), such as a VNU stage 136. The decoder 132 may further include a set of check node units (CNUs), such as a CNU stage 144. The decoder 132 may further include a row-wise shifter 140. The row-wise shifter 140 may be coupled to an output of the VNU stage 136 and may be further coupled to an input of the CNU stage 144.

The ECC engine 120 is configured to receive data and to generate one or more ECC codewords based on the data. For example, the encoder 124 may be configured to encode data using a low-density parity check (LDPC) encoding technique. The encoder 124 may include a Hamming encoder, a Reed-Solomon (RS) encoder, a Bose-Chaudhuri-Hocquenghem (BCH) encoder, an LDPC encoder, a turbo encoder, an encoder configured to encode data according to one or more other ECC techniques, or a combination thereof. The ECC engine 120 is configured to decode data accessed from the memory 104. For example, the decoder 132 within the ECC engine 120 may be configured to decode data accessed from the memory 104 to detect and correct one or more errors that may be present in the read data, up to an error correcting capacity of the particular ECC scheme.

The controller 110 is configured to receive data and instructions from the host device 156 and to send data to the host device 156. For example, the controller 110 may send data to the host device 156 via the host interface 152 and may receive data from the host device 156 via the host interface 152.

The controller 110 is configured to send data and commands to the memory 104 and to receive data from the memory 104. For example, the controller 110 is configured to send data and a write command to cause the memory 104 to store the data to a specified address of the memory 104. The write command may specify a physical address of a portion of the memory 104 (e.g., a physical address of a word line of the memory 104) that is to store the data. The controller 110 is configured to send a read command to the memory 104 to access data from a specified address of the memory 104. The read command may specify the physical address of a portion of the memory 104 (e.g., a physical address of a word line of the memory 104).

The host device 156 may correspond to a mobile telephone, a music player, a video player, a gaming device or console, an electronic book reader, a personal digital assistant (PDA), a computer, such as a laptop, a tablet, or a notebook computer, a portable navigation device, another electronic device, or a combination thereof. The host device 156 may communicate via a host controller, which may enable the host device 156 to communicate with the data storage device 102. The host device 156 may operate in compliance with a JEDEC Solid State Technology Association industry specification, such as an embedded MultiMedia Card (eMMC) specification or a Universal Flash Storage (UFS) Host Controller Interface specification. The host device 156 may operate in compliance with one or more other specifications, such as a Secure Digital (SD) Host Controller specification as an illustrative example. Alternatively, the host device 156 may communicate with the data storage device 102 in accordance with another communication protocol.

In operation, the controller 110 may receive data from the host device 156 via the host interface 152. The controller 110 may input the data to the encoder 124 to generate one or more ECC codewords. For example, the encoder 124 may encode the data using an LDPC encoding technique to generate one or more ECC codewords.

The controller 110 may store the one or more ECC codewords to the memory 104. For example, the controller 110 may store data 108 to the memory 104, and the data 108 may include the one or more ECC codewords.

The controller 110 may receive a request for read access to the data 108 from the host device 156 via the host interface 152. In response to receiving the request for read access, the controller 110 may cause the read/write circuitry 106 to sense the data 108. For example, the controller 110 may send one or more control signals to the read/write circuitry 106. The one or more control signals may indicate a physical address associated with the data 108 and/or one or more techniques for accessing the data 108 (e.g., a “hard” read technique and/or a “soft” read technique).

The read/write circuitry 106 may provide the sensed data to the controller 110. For example, the read/write circuitry 106 may provide sensed data 116 to the controller 110. The sensed data 116 may include hard bits, soft bits, or a combination thereof. For example, in a particular implementation, the sensed data 116 includes hard bits and does not include soft bits. In this case, the sensed data 116 may include a hard bit corresponding to the value 109. In one or more other implementations, the sensed data 116 may include soft bits (e.g., one hard bit and one or more soft bits per bit value of the data 108). In this example, the sensed data 116 may include a hard bit corresponding to the value 109 and one or more soft bits corresponding to the value 109. It is noted that the sensed data 116 may include one or more errors, such as write errors caused during writing of the data 108 to the memory 104, errors caused during storage of the data 108 (e.g., due to noise, cross coupling effects, charge leakage, etc.), and/or read errors caused during sensing of the data 108.

The controller 110 may input the sensed data 116 to the ECC engine 120 to initiate a decoding process to correct one or more errors of the sensed data 116. In a particular embodiment, the decoding process is an LDPC decoding process performed by the decoder 132. The LDPC decoding process may use a parity check matrix represented by data 118 to correct one or more errors of the sensed data 116. The parity check matrix may be a quasi-cyclic (QC) LDPC parity check matrix. Example 1 illustrates a non-limiting example of a parity check matrix H that may be indicated by the data 118.

### Example 1

$$H = [ \begin{matrix}{P}_{11} & 0 & 0 & 0 & {P}_{15} & 0 & 0 & 0 & … & {P}_{1 G} \\ 0 & {P}_{12} & 0 & 0 & 0 & 0 & {P}_{17} & 0 & … & 0 \\ 0 & 0 & 0 & {P}_{14} & 0 & 0 & 0 & 0 & … & 0 \\ {P}_{21} & 0 & 0 & 0 & 0 & {P}_{16} & 0 & 0 & … & 0 \\ 0 & 0 & {P}_{13} & 0 & 0 & 0 & 0 & {P}_{18} & … & 0 \\ 0 & 0 & 0 & 0 & {P}_{25} & 0 & 0 & 0 & … & 0 \\ 0 & 0 & 0 & 0 & 0 & {P}_{26} & 0 & 0 & … & 0 \\ 0 & 0 & 0 & {P}_{24} & 0 & 0 & 0 & 0 & … & 0 \\ 0 & 0 & {P}_{23} & 0 & 0 & 0 & {P}_{27} & 0 & … & 0 \\ 0 & {P}_{22} & 0 & 0 & 0 & 0 & 0 & {P}_{28} & … & {P}_{2 G}\end{matrix} ]$$

In Example 1, each element may represent a sub-matrix that includes multiple values (i.e., each individual element may be expanded to a sub-matrix). For example, if H is a QC parity check matrix, the elements P may correspond to cyclic permutations of an identity matrix. Each element 0 may correspond to a null sub-matrix, and G may indicate a positive integer number of columns of the parity check matrix H.

In a particular implementation, the VNU stage 136 is configured to generate variable node messages using a table-based technique. To illustrate, the VNU stage 136 may be configured to map a hard bit to a variable node message value. In an illustrative implementation, the VNU stage 136 includes combinatorial logic circuitry configured based on a Karnaugh mapping table of hard bits to variable node message values. As a result, the VNU stage 136 may generate variable node message values (e.g., LLRs) using a “non-linear” technique (e.g., based on a mapping table) instead of performing parity check operations to generate LLRs. For example, the VNU stage 136 may generate a variable node message 138.

The VNU stage 136 may be configured to provide the variable node message 138 to the row-wise shifter 140. The row-wise shifter 140 may be configured to shift values generated by VNUs of the VNU stage 136 to “distribute” the values to CNUs of the CNU stage 144. The row-wise shifter 140 may row-shift the variable node message 138 (instead of column-shifting the variable node message 138) to generate a row-shifted variable node message 142. The row-wise shifter 140 may be configured to provide the row-shifted variable node message 142 to the CNU stage 144.

To further illustrate, a decoder may implement a quasi-cyclic parity check matrix, such as the illustrative parity check matrix of Example 1. In a quasi-cyclic parity check matrix, each non-zero sub-matrix corresponds to a shifted version of an identity matrix. For example, a particular sub-matrix may have entries that are right-shifted (or “permuted”) by a particular shift value (e.g., by one position, two positions, etc.) relative to an identity matrix. The row-wise shifter 140 may row-shift values of the variable node message 138 that correspond to the particular sub-matrix based on the shift value (e.g., by one position, two positions, etc.).

The CNU stage 144 may generate a check node message 146 based on the row-shifted variable node message 142. In a particular embodiment, the CNU stage 144 is configured to generate the check node message 146 without using second minimum (min2) values included in the row-shifted variable node message 142. To illustrate, conventional LDPC CNUs typically generate check node messages by performing operations that utilize first minimum (min1) and second minimum (min2) selected from a group of LLRs. In this case, data values may be updated based on the min1 and min2 values (e.g., by updating values that the min1 and min2 values indicate to be “correct”). However, such check node processing operations may utilize processing and memory resources to calculate and store the min1 and min2 values. The CNU stage 144 of FIG. 1 may correspond to a min1-based CNU stage that does not utilize min2 values. For example, as described further below, the CNU stage 144 may utilize a flag bit that indicates a magnitude of a min1 value instead of calculating and storing a min2 value. The flag bit may include a single bit and may be selected using a simple selection process, which may reduce decoder complexity relative to a decoder that computes and stores min2 values.

The variable node message 138 and the check node message 146 may indicate reliability of bit values of the sensed data 116, such as log-likelihood ratios (LLRs) associated with bit values of the sensed data 116. The decoder 132 may decode the sensed data 116 by iteratively updating the LLRs and passing the LLRs between the VNU stage 136 and the CNU stage 144. The decoding process may continue until a set of parity equations specified by a parity check matrix is satisfied. For example, data errors may be iteratively corrected until the decoding process converges on a particular set of bit values corresponding to a valid ECC codeword. In some circumstances, an error rate of the sensed data 116 may exceed an error correction capability associated with the particular ECC scheme. In this case, the decoding process may time out without converging on a valid ECC codeword, such as in response to iterating the decoding process a threshold number of iterations without converging on a valid ECC codeword.

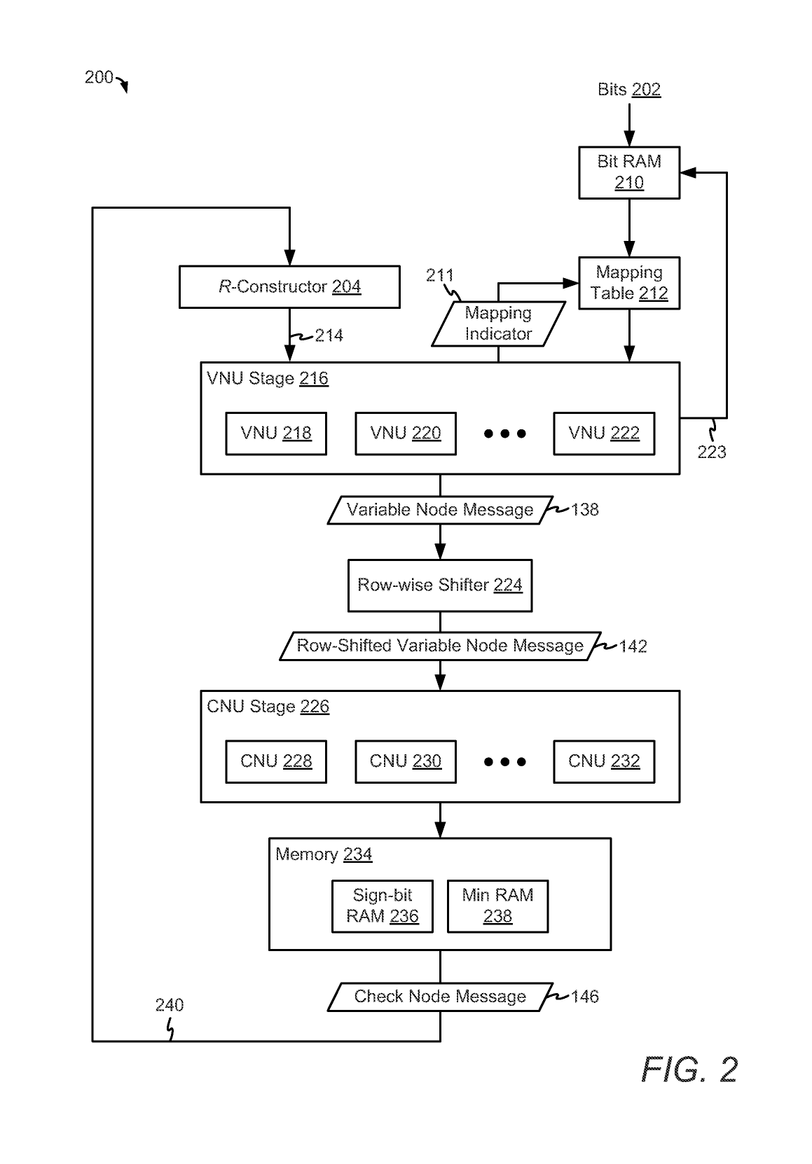

FIG. 1 illustrates example operations and structures that may improve performance of a decoder. For example, implementing a min1-based CNU stage within a decoder may improve decoder performance by reducing a number of calculations performed by the decoder during decoding operations. Additional illustrative examples are described further with reference to FIGS. 2-9.

Referring to FIG. 2, a particular illustrative embodiment of a device is depicted and generally designated 200. The device 200 may be included within the data storage device 102. For example, the device 200 may be integrated within the decoder 132.

The device 200 may include a check node message constructor (“R-constructor”) 204, a bit RAM 210, a variable node unit (VNU) stage 216, a row-wise shifter 224, a check node unit (CNU) stage 226, and a memory 234. The VNU stage 216 may correspond to the VNU stage 136 of FIG. 1, the row-wise shifter 224 may correspond to the row-wise shifter 140 of FIG. 1, and the CNU stage 226 may correspond to the CNU stage 144 of FIG. 1.

The VNU stage 216 may access a mapping table 212, such as by using a mapping indicator 211. The VNU stage 216 may include one or more variable node units, such as a VNU 218, a VNU 220, and a VNU 222. The CNU stage 226 may include one or more check node units, such as a CNU 228, a CNU 230, and a CNU 232. The VNU stage 216 may be coupled to the R-constructor 204, such as via a path 214 (e.g., one or more wires or one or more pipeline registers, etc.).

The bit RAM 210 may store bits 202 sensed from the memory 104 of FIG. 1. The bits 202 may correspond to the sensed data 116. The bits 202 may be input to the bit RAM 210 and then input to the VNU stage 216 to initiate a decoding process at the device 200. In a particular embodiment, the bits 202 include only “hard” bits sensed from the memory 104 by the read/write circuitry 106 using a hard read technique. Alternatively or in addition, the bits 202 may include “soft” bits sensed from the memory 104 by the read/write circuitry 106 using a soft read technique. The bit RAM 210 may be coupled to the VNU stage 216, such as via a path 223 (e.g., one or more wires or one or more pipeline registers, etc.).

The memory 234 may include a sign-bit RAM 236 and a “minimum” value RAM (“min RAM”) 238. The memory 234 may be coupled to the R-constructor 204, such as via a feedback path 240 (e.g., one or more wires or one or more pipeline registers, etc.).

In operation, the bits 202 may be input to the bit RAM 210 (e.g., by the controller 110 of FIG. 1) to initiate an iteration of a decoding process using the bits 202. Depending on the particular implementation, the bits 202 may be mapped to values using the mapping table 212 and the values may be provided to the VNU stage 216, or the bits 202 may be provided directly to the VNU stage 216 using a path from the bit RAM 210 to an input of the VNU stage 216 (not shown in the example of FIG. 2).

The VNU stage 216 may be configured to perform variable node processing operations to generate a variable node message, such as the variable node message 138, based on the bits 202. The variable node message 138 may indicate which values of an input message (e.g., the bits 202) are likely to be “correct” based on the variable node processing operations. The row-wise shifter 224 may row-shift values of the variable node message 138 to generate a row-shifted variable node message, such as the row-shifted variable node message 142. The row-wise shifter 224 may provide the row-shifted variable node message 142 to the CNU stage 226.

The CNU stage 144 may be configured to perform check node processing operations to generate a check node message, such as the check node message 146. The check node message 146 may indicate which bits of an input message (e.g., the variable node message 138) are likely to be “correct” based on the check node processing operations. The check node message 146 may be stored at the memory 234, such as at the sign-bit RAM 236 and at the min RAM 238. The check node message may be provided to the VNU stage 216, such as via the feedback path 240.

The device 200 may initiate a subsequent iteration of the decoding process using the check node message, such as by performing variable node processing operations at the VNU stage 216. The decoding process may continue until either the decoding process converges on a valid ECC codeword or the decoding process times out (e.g., if a certain number of iterations occur without converging to a valid ECC codeword).

In a particular embodiment, the device 200 is configured to perform decoding processes according to a simplified (or “stripped”) “minimum-sum” (min-sum) LDPC decoding technique. Example 2 illustrates example pseudo-code corresponding to an illustrative stripped min-sum LDPC decoding technique that can be implemented at the device 200.

### Example 2

```
Initialization :
iter ← 0; check ← 1; R_{i, j}^{′} ← 0; Lⱼ ← LUT(cⱼ)
while(iter < maxᵢₜₑᵣ & & check ~= 0)
{
  VNU : for i ε M(j), R_{i, j}^{′} ← {min 1ᵢ^{′},T,indexᵢ^{′},Qs_{i, j}^{′}},
    ${Q}_{i , j} ← {L}_{j} + {\sum }_{{i}^{′} ∈ M ( j ) \backslash i}^{ } {R}_{{i}^{′} , j}^{′} , {Q}_{j} ← {L}_{j} + {\sum }_{{i}^{′} ∈ M ( j )}^{ } {R}_{{i}^{′} , j}^{′}$
  $CNU : \{ {min}_{i , j} , {Qs}_{i , j} \} ← \{ {\prod }_{{j}^{′} ∈ N ( i ) \backslash j}^{ } sign ( {Q}_{i , {j}^{′}} ) , {min}_{{j}^{′} ∈ N ( i ) \backslash j} ( \vert {Q}_{i , {j}^{′}} \vert ) \}$
    $\{ min {1}_{i} , T , {index}_{i} , {⋃}_{j ∈ N ( i )} ( {Qs}_{i , j} ) \} ← {⋃}_{j ∈ N ( i )} \{ {min}_{i , j} , {Qs}_{i , j} \}$
Hard decision based on Qⱼ;convergency check.
}
```

In Example 2, iter indicates a number of decoding iterations associated with a decoding process, and check indicates a convergence status of the decoding process (e.g., “1” if the decoding process has not converged to a valid codeword, and “0” if the decoding process has converged to a valid codeword). R_{i,j} indicates an updated (or “new”) check node message to a jth symbol connected to an ith check node, and R′_{i,j} indicates a previous (or “old”) check node message to the jth symbol connected to the ith check node. Lⱼ indicates an a priori LLR message of the jth symbol, and LUT(cⱼ) indicates a value associated with a lookup table (e.g., the mapping table 212) corresponding to a jth bit of data c to be decoded (e.g., the bits 202). Further, maxᵢₜₑᵣ indicates a number of iterations of the decoding process without converging to a valid codeword before the decoding process “times out” (or fails). Q_{i,j} indicates a variable node message of the jth symbol connected to the ith check node, Q′ⱼ indicates a previous (or “old”) a posteriori LLR message of the jth symbol, and Qⱼ indicates an updated (or “new”) a posteriori LLR message of the jth symbol. In Example 2, T may indicate a flag value signifying a same bit. For example, T may indicate whether a mint value and a min2 value are equal (min1==min2) Indexᵢ indicates a memory location storing an LLR value equal to mint, and Qs_{i,j} indicates an updated sign value of location (i, j) with

$${Qs}_{i , j} = {\prod }_{{j}^{′} ∈ N ( i ) \backslash j}^{ } sign ( {Q}_{i , {j}^{′}} ) .$$

N(i) indicates a variable node set connected to the ith check node, and M(j) may indicate a check node set connected to the jth variable node.

In a particular example, memory bandwidth utilization is reduced at the device 200 by using a flooding LDPC decoding technique. The flooding LDPC decoding technique may include updating all check node values prior to updating variable node values (and vice versa). To illustrate, certain conventional layered LDPC decoding techniques update variable nodes as soon as updated values are available by dividing information into layers and by processing the layers simultaneously, which may increase bandwidth utilization. In some cases, the layers may be mutually dependent, such as when processing of one layer depends on other layers. Thus, layered decoding may be associated with a large memory size and high computational complexity. In accordance with the present disclosure, bandwidth utilization of a decoder may be reduced by using a flooding LDPC decoding technique. For example, a number of shift units of the row-wise shifter 224 and/or a storage size of the memory 234 may be reduced as compared to a decoder that utilizes a layered LDPC decoding technique. The flooding LDPC decoding technique may have slower convergence speed relative to a layered decoding technique (e.g., more iterations may be used to converge to a valid codeword). However, slower convergence speed may be acceptable in some circumstances, such as at a “beginning-of-life” stage of operation of a device (before physical wear occurs at the device) and when fewer data errors are expected at the device. In this case, overall device performance may be improved by decreasing convergence speed in order to simplify decoding operations and to reduce decoder bandwidth utilization, which may enable simplified and less costly decoder structures (e.g., a smaller memory size, a smaller bus size, etc.).

The example of FIG. 2 illustrates that the VNU stage 216 may use a lookup table, such as the mapping table 212. The mapping table 212 may reduce complexity of VNU processing operations. For example, the mapping table 212 may map hard bits to variable node message values, which may reduce complexity of operations at the VNU stage 216 as compared to a decoder that uses parity check operations to generate variable node message values.

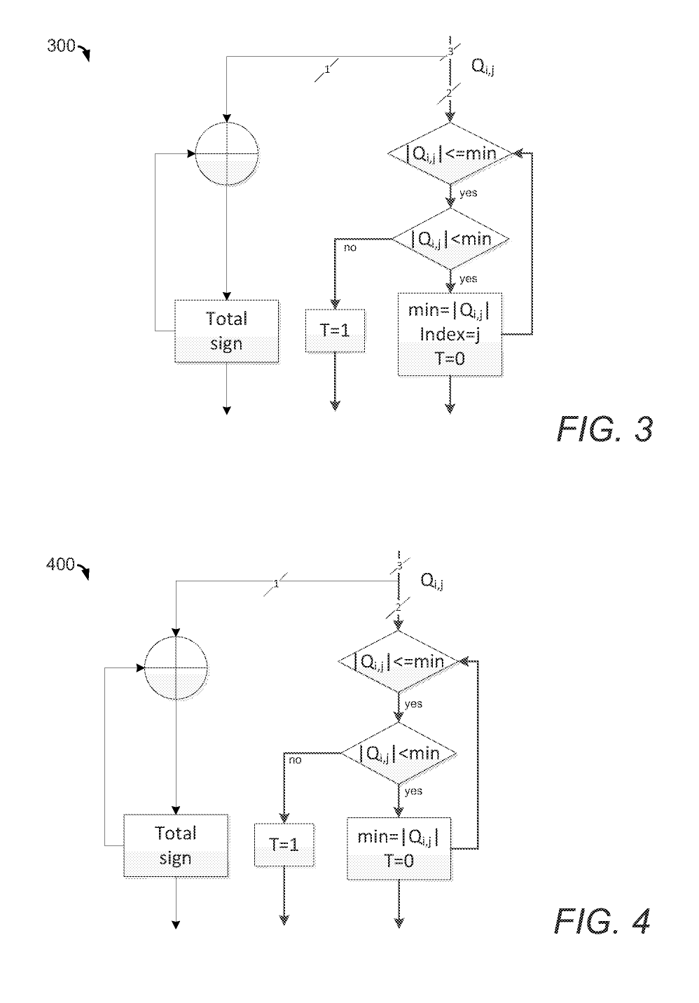

FIG. 3 is a data flow diagram of a particular illustrative example of a process 300. The process 300 may be performed at a CNU, such as at one or more of the CNUs 228, 230, and 232 of FIG. 2.

The process 300 illustrates that a variable node message value (Q_{i,j}) can be used to determine a check node message that includes a sign bit (total sign), a flag bit (T), a min1 value (min), and an index value (index). The flag bit (T) may have a value (e.g., zero or one) indicating whether a min1 value satisfies a threshold. The threshold may correspond to the variable node message value (Q_{i,j}). In the process 300, an exclusive-or (XOR) operation may be performed using the variable node message value (Q_{i,j}) and the sign bit (total sign). In a particular embodiment, the process 300 can be implemented at a decoder instead of using a conventional decoding process that performs check node processing using min2 values. For example, the process 300 may utilize the flag bit (T) instead of using min2 values. To further illustrate, Example 3 indicates example pseudo-code illustrating an example implementation of the process 300.

### Example 3

```
input Q_{i,j}
if (min 1ᵢ > |Q_{i,j}|)
  T ← 0
  min 1ᵢ ← |Q_{i,j}|
  indexᵢ ← j
elseif (min 1ᵢ == |Q_{i,j}|)
  T ← 1
Qsᵢ = Qsᵢ ⊕ sign(Q_{i,j} )
store {Qsᵢ, T , min 1,index}
store {sign(Q_{i,j})}
reconstruct R,
if (T == 0) & &(j == index)
  R_{i,j} ← {Qsᵢ ⊕ sign(Q_{i,j} ), max_val}
else
  R_{i,j} ← {Qsᵢ ⊕ sign(Q_{i,j} ), min 1}
```

In Example 3, “s” indicates a XOR operation,

$${Qs}_{i} = {\prod }_{{j}^{′} ∈ N ( i )}^{ } sign ( {Q}_{i , {j}^{′}} ) ,$$

and max_val indicates the “maximum” magnitude of Q_{i,j}. For example, max_val=3 in an illustrative 3-bit implementation (e.g., one hard bit and two soft bits per data value sensed from the memory 104).

The process 300 and Example 3 each illustrate techniques for avoiding using min2 values in check node processing, such as by using a flag bit (T) to indicate whether a min1 value (min) satisfies a threshold. For example, the flag bit may indicate whether the min1 value is greater than a variable node message value (Q_{i,j}). The flag bit may include a single bit indicating a magnitude of the min1 value relative to the threshold, which may reduce complexity of certain decoder operations relative to a conventional check node processing technique that calculates and stores a multi-bit min2 value in addition to a min1 value. Thus, in this case calculating and storing a min2 value may be avoided.

FIG. 4 is a data flow diagram of a particular illustrative example of a process 400. The process 400 may be performed at a CNU, such as at one or more of the CNUs 228, 230, and 232 of FIG. 2.

The process 400 illustrates that a variable node message value (Q_{i,j}) can be used to determine a check node message that includes a sign bit (total sign), a flag bit (T), and a min1 value (min) The flag bit (T) may have a value (e.g., zero or one) indicating whether the min1 value satisfies a threshold (e.g., a variable node message value (Q_{i,j}). In the process 400, a XOR operation may be performed using the variable node message value (Q_{i,j}) and the sign bit (total sign). In a particular embodiment, the process 400 can be implemented at a decoder instead of using a conventional decoding process that performs check node processing using min2 values. For example, the process 400 may utilize the flag bit (T) instead of using min2 values. Further, decoding operations in the process 400 are simplified by avoiding storing an index value. To further illustrate, Example 4 indicates example pseudo-code illustrating an example implementation of the process 400.

### Example 4

```
input Q_{i,j}
if (min 1 > |Q_{i,j}|)
  T ← 0
  min 1 ← |Q_{i,j}|
elseif (min 1 == |Q_{i,j}|)
  T ← 1
Qsᵢ = Qsᵢ ⊕ sign(Q_{i,j} )
store {Qsᵢ, T , min 1}
store{Q_{i,j} }
reconstruct R,
if (T == 0) & &(|Q_{i,j}| == min 1)
  R_{i,j} ← {Qsᵢ ⊕ sign(Q_{i,j} ), max_val}
else
  R_{i,j} ← {Qsᵢ ⊕ sign(Q_{i,j} ), min 1}
```

In Example 4,

$${Qs}_{i} = {\prod }_{{j}^{′} ∈ N ( i )}^{ } sign ( {Q}_{i , {j}^{′}} ) ,$$

and max_val indicates the “maximum” magnitude of Q_{i,j}. For example, max_val=3 in an illustrative 3-bit implementation (e.g., one hard bit and two soft bits per data value sensed from the memory 104).

The process 400 and Example 4 each illustrate techniques for avoiding using min2 values in check node processing. For example, by using a flag bit (T) that indicates whether a min1 value (min) satisfies a threshold (e.g., a variable node message value (Q_{i,j}), calculating and storing a min2 value may be avoided. The process 400 and Example 4 further illustrate that storing of an index (e.g., the index value described with reference to the process 300 and Example 3) may be avoided.

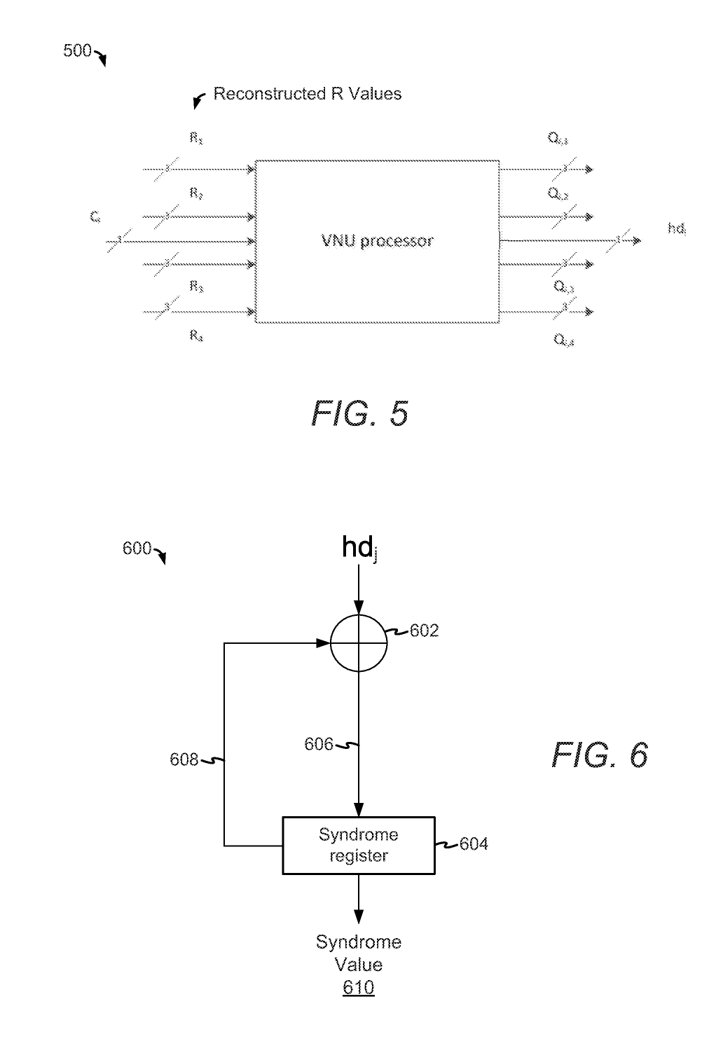

Referring to FIG. 5, a particular illustrative example of a VNU processor is depicted and generally designated 500. The VNU processor 500 may be implemented within a VNU stage, such as the VNU stage 216 of FIG. 2. For example, the VNU processor 500 may be implemented in one or more of the VNUs 218, 220, and 222 of FIG. 2.

The VNU processor 500 may be responsive to a bit, such as a hard bit (cᵢ). The hard bit may correspond to a bit of the data 108 of FIG. 1. The VNU processor 500 may be further responsive to reconstructed R values (R₁, R₂, R₃, and R₄). In an illustrative implementation, the reconstructed R values are generated by the R-constructor 204 of FIG. 2. The reconstructed R values may be provided to the VNU processor 500 via the path 214.

The VNU processor 500 may be configured to perform variable node processing using the hard bit (cᵢ) and the reconstructed R values to generate variable node message values (Q_{i,1}, Q_{i,2}, Q_{i,3}, and Q_{i,4}). The VNU processor 500 may be configured to generate an output bit, such as a hard decision bit (hdᵢ). In a particular embodiment, the VNU processor 500 is configured to perform variable node processing (e.g., to generate the variable node message values and the hard decision bit) in accordance with Example 5.

### Example 5

$${Q}_{i , j} ← {L}_{j} + {\sum }_{{i}^{′} ∈ M ( j ) \backslash i} {R}_{{i}^{'} , j}^{′} , \\ {Q}_{j} ← {L}_{j} + {\sum }_{{i}^{′} ∈ M ( j )} {R}_{{i}^{'} , j}^{′} , \\ {Hd}_{j} = sign ( {Q}_{j} )$$

In an illustrative implementation, variable node message values (i.e., Q_{i,j}, such as Q_{i,1}, Q_{i,2}, Q_{i,3}, and Q_{i,4} in the example of FIG. 4) are selected using a lookup table, such as the mapping table 212 of FIG. 2. A particular illustrative example of a lookup table is illustrated in Example 6.

### Example 6

$$Qtmp = L + {\sum }_{{i}^{′} ∈ M ( j ) \backslash i} {R}_{{i}^{′}} = L + {R}_{1} + {R}_{2}$$

$$Q = \{ \begin{matrix}- 3 , & Qtmp < - 3 \\ - 2 , & Qtmp = - 3 \\ - 1 , & Qtmp == - 2 \&\& Qtmp == - 1 \\ 0 , & if Qtmp == 0 \\ 1 , & Qtmp == 2 \&\& Qtmp == 1 \\ 2 , & Qtmp == 3 \\ 3 , & Qtmp > 3\end{matrix} \\ L \text{:} 1 - bit , \\ {R}_{1} \text{:} 3 - bit \{ {r}_{11} , {r}_{12} , {r}_{13} \} \\ {R}_{2} \text{:} 3 - bit \{ {r}_{21} , {r}_{22} , {r}_{23} \} \\ Q \text{:} 3 - bit \{ {q}_{1} , {q}_{2} , {q}_{3} \}$$

Example 6 illustrates that a variable node message value (Q) can be selected by mapping a temporary value (Qtmp) to a value (e.g., −3, −2, −1, 0, 1, 2, or 3). The temporary value may be calculated by the VNU processor 500, such as in accordance with the sample equation illustrated in Example 6. The temporary value may be specified by the mapping indicator 211 of FIG. 2, and the VNU processor 500 may determine a variable node message value by accessing the mapping table 212 using the temporary value.

In Example 6, values (e.g., L, R₁, R₂, and Q) may be generated based on sub-values (e.g., a set of r_{i,j} values, such as r₁₁, r₁₂, r₁₃, r₂₁, r₂₂, r₂₃, q₁, q₂, and q₃). Example 7 illustrates sample equations for generating the sub-values. In Example 7, each sub-value r_{i,j} corresponds to a bit of Rᵢ. As an example, Rᵢ may include three bits, with r_{i,1} corresponding to the first bit value of Rᵢ, r_{i,2} corresponding to the second bit value of Rᵢ, and r_{i,3} corresponding to the third bit value of Rᵢ. In this illustrative example, the bitwidth of Rᵢ is equal to three. In other examples, the bitwidth of Rᵢ may be another number, such as two, which may be implemented in connection with a low cost decoder, as an illustrative example.

### Example 7

$${q}_{1} = \overline{L} ( {r}_{21} {\overline{r}}_{22} {\overline{r}}_{23} + {r}_{11} {\overline{r}}_{12} {\overline{r}}_{13} + {r}_{11} {\overline{r}}_{12} {r}_{21} {\overline{r}}_{22} ) + L ( \overline{{r}_{21} {\overline{r}}_{22} {\overline{r}}_{23} + {r}_{11} {\overline{r}}_{12} {\overline{r}}_{13} + {\overline{r}}_{11} {r}_{12} {\overline{r}}_{21} {r}_{22} {r}_{23} + {\overline{r}}_{11} {r}_{12} {r}_{13} {\overline{r}}_{21} {r}_{22}} )$$

$${q}_{2} = \overline{L} ( \begin{matrix}\overline{{r}_{11} {r}_{12} {\overline{r}}_{13} + {r}_{11} {\overline{r}}_{13} {r}_{21} + {r}_{21} {\overline{r}}_{22} {\overline{r}}_{23} + {r}_{11} {\overline{r}}_{12} {\overline{r}}_{13} + {\overline{r}}_{12} {\overline{r}}_{13} {r}_{21} {\overline{r}}_{22} +} \\ \overline{{r}_{11} {\overline{r}}_{12} {\overline{r}}_{22} {\overline{r}}_{23} + {r}_{11} {\overline{r}}_{12} {r}_{21} {r}_{22} + {r}_{11} {r}_{12} {r}_{21} {\overline{r}}_{22}}\end{matrix} ) + L ( \begin{matrix}{r}_{21} {\overline{r}}_{22} {\overline{r}}_{23} + {r}_{11} {\overline{r}}_{12} {\overline{r}}_{13} + {\overline{r}}_{11} {\overline{r}}_{12} {\overline{r}}_{21} {r}_{22} + {\overline{r}}_{12} {\overline{r}}_{13} {\overline{r}}_{21} {r}_{22} + {\overline{r}}_{11} {r}_{12} {\overline{r}}_{21} {r}_{22} + \\ {\overline{r}}_{11} {r}_{12} {\overline{r}}_{22} {r}_{23} + {\overline{r}}_{11} {\overline{r}}_{13} {\overline{r}}_{21} {r}_{22} {\overline{r}}_{23} + {\overline{r}}_{11} {\overline{r}}_{12} {r}_{13} {\overline{r}}_{21} {r}_{23} + {\overline{r}}_{11} {r}_{13} {\overline{r}}_{21} {\overline{r}}_{22} {r}_{23} + \\ {\overline{r}}_{11} {r}_{12} {\overline{r}}_{13} {\overline{r}}_{21} {\overline{r}}_{23} + {\overline{r}}_{11} {r}_{12} {r}_{13} {r}_{21} {r}_{22} {r}_{23} + {r}_{11} {r}_{12} {r}_{13} {\overline{r}}_{21} {r}_{22} {r}_{23}\end{matrix} ) \\ {q}_{3} = \overline{L} ( \begin{matrix}{r}_{21} {\overline{r}}_{22} {\overline{r}}_{23} + {r}_{11} {\overline{r}}_{12} {\overline{r}}_{13} + {\overline{r}}_{12} {\overline{r}}_{13} {r}_{21} {\overline{r}}_{23} + {r}_{11} {\overline{r}}_{12} {r}_{21} {\overline{r}}_{23} + \\ {r}_{11} {\overline{r}}_{13} {\overline{r}}_{22} {\overline{r}}_{23} + {r}_{11} {\overline{r}}_{13} {r}_{21} {\overline{r}}_{22} + {\overline{r}}_{11} {\overline{r}}_{12} {r}_{13} {r}_{21} {\overline{r}}_{22} + \\ {r}_{11} {\overline{r}}_{12} {\overline{r}}_{21} {\overline{r}}_{22} {r}_{23} + {r}_{11} {r}_{12} {r}_{13} {r}_{21} {r}_{22} {r}_{23}\end{matrix} ) + \begin{matrix}L ( \begin{matrix}{r}_{21} {\overline{r}}_{22} {\overline{r}}_{23} + {r}_{11} {\overline{r}}_{12} {\overline{r}}_{13} + {\overline{r}}_{12} {\overline{r}}_{13} {\overline{r}}_{21} {\overline{r}}_{22} {r}_{23} + {\overline{r}}_{11} {r}_{12} {\overline{r}}_{13} {\overline{r}}_{21} {\overline{r}}_{23} + \\ {\overline{r}}_{11} {\overline{r}}_{12} {\overline{r}}_{13} {\overline{r}}_{22} {r}_{23} + {\overline{r}}_{11} {r}_{12} {\overline{r}}_{13} {\overline{r}}_{21} {r}_{22} {r}_{23} + \\ {\overline{r}}_{11} {r}_{12} {r}_{13} {\overline{r}}_{21} {r}_{22} {\overline{r}}_{23} + \\ {\overline{r}}_{11} {r}_{12} {r}_{13} {r}_{21} {r}_{22} {r}_{23} + {r}_{11} {r}_{12} {r}_{13} {\overline{r}}_{21} {r}_{22} {r}_{23}\end{matrix} )\end{matrix}$$

The techniques illustrated with reference to FIG. 5 and Examples 5-7 facilitate improved variable node processing operations. For example, by utilizing a lookup table in connection with variable node processing operations, computationally intensive operations can be reduced or avoided. As a result, decoding operations may be performed more quickly and/or may utilize less power as compared to a device that utilizes conventional decoding techniques.

Referring to FIG. 6, a particular illustrative embodiment of an on-the-fly syndrome value generator is depicted and generally designated 600. The on-the-fly syndrome value generator 600 may be included in the data storage device 102 of FIG. 1, such as within the decoder 132.

The on-the-fly syndrome value generator 600 includes a XOR module 602, such as one or more logic gates configured to perform XOR operations. The XOR module 602 may be coupled to a syndrome register 604. For example, the XOR module 602 may be coupled to the syndrome register 604 via a path 606. As another example, the XOR module 602 may be coupled to the syndrome register 604 via a feedback path 608.

During operation, the XOR module 602 may be responsive to an input bit, such as a bit (hdⱼ). The syndrome register 604 may be configured to generate a syndrome value 610 based on an output of the XOR module 602. The syndrome value 610 may be used in connection with certain decoding operations, such as in connection with check node processing associated with an LDPC decoding process. In this case, the on-the-fly syndrome value generator 600 may be integrated within the CNU stage 226 of FIG. 2.

The on-the-fly syndrome value generator 600 illustrates fast and simple syndrome value generation, which may be utilized in connection with a flooding scheduling decoder. Further, the on-the-fly syndrome value generator 600 of FIG. 6 may reduce complexity of decoding operations at a decoder. For example, in some applications, generating a syndrome value using the techniques of FIG. 6 may be simplified as compared to certain trellis-based LDPC decoding techniques that calculate syndrome values using min1 and min2 values. Thus, the techniques of FIG. 6 may improve decoder performance by enhancing speed of decoder operations and/or by reducing power consumption of a decoder.

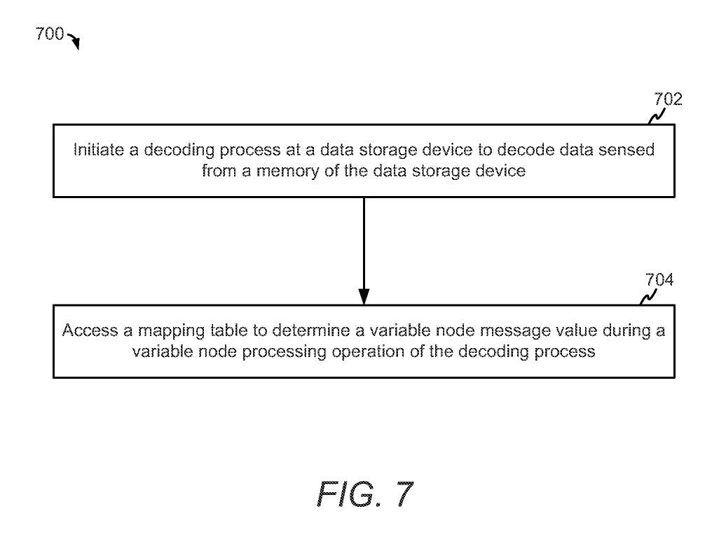

Referring to FIG. 7, a particular illustrative embodiment of a method is depicted and generally designated 700. The method 700 may be performed at the data storage device 102, such as by the decoder 132. In a particular embodiment, the method 700 is performed in response to receiving a request from the host device 156 for read access to data stored at the memory 104, such as the data 108.

The method 700 includes initiating a decoding process at a data storage device to decode data sensed from a memory of the data storage device, at 702. The memory may correspond to the memory 104, and the data storage device may correspond to the data storage device 102. The data may correspond to the sensed data 116 and/or the bits 202. To illustrate, the decoding process may be initiated by sensing the data 108 to generate the sensed data 116 and by inputting the sensed data 116 to the decoder 132.

The method 700 further includes accessing a mapping table to determine a variable node message value during a variable node processing operation of the decoding process, at 704. The mapping table may correspond to the mapping table 212, and the variable node message value may correspond to a variable node message value described herein (e.g., a Q value, such as any of the variable node message values Q_{i,1}, Q_{i,2}, Q_{i,3}, and Q_{i,4} described with reference to FIG. 5). In a particular embodiment, the variable node processing operation is performed at the VNU stage 136 or at the VNU stage 216, such as by one of the VNUs 218, 220, and 222. The variable node processing operation can be performed by the VNU processor 500.

In a particular embodiment, the mapping table is accessed by a VNU processor, such as the VNU processor 500, using a mapping indicator to select the variable node message value during the variable node processing operation. The mapping indicator may correspond to the temporary value (Qtmp) of Example 6.

The method 700 may optionally include providing a variable node message to a row-wise shifter, where the variable node message includes the variable node message value. The variable node message may correspond to the variable node message 138, and the row-wise shifter may correspond to any of the row-wise shifters 140, 224. The row-wise shifter may be configured to row-shift the variable node message to generate a row-shifted variable node message, such as the row-shifted variable node message 142.

The method 700 may optionally include determining a check node message value using the row-shifted variable node message and without determining a second minimum (min2) value during a check node processing operation of the decoding process. The check node processing operation may be performed at the CNU stage 144 or at the CNU stage 226, such as by one of the CNUs 228, 230, and 232. The check node message value may be included in the check node message R_{i,j} described with reference to Example 2.

In at least one embodiment, the check node processing operation includes storing an index value (e.g., index of FIGS. 3-4 and Examples 3-4) indicating a variable node (e.g., a variable node having an index value of j) associated with the check node message value. For example, the CNU may be configured to store the index value indicating a variable node associated with the check node message value. In this example, the check node message value may be determined based on the techniques of FIG. 3 and Example 3 (e.g., by setting index j, as illustrated by the process 300 of FIG. 3).

In another embodiment, determining the check node message value does not include storing an index value indicating a variable node associated with the check node message value. For example, the CNU may be configured to determine the check node message value without storing the index value. In this example, the check node message value may be determined based on the techniques of FIG. 4 and Example 4.

The variable node processing operation and the check node processing operation may include adjusting one or more values of the data based on a set of parity check equations associated with a parity check matrix. For example, as described with reference to FIG. 1, the data 118 may indicate a parity check matrix. The parity check matrix may specify the set of parity check equations. The variable node processing operation and the check node processing operation may include adjusting one or more values of the data to cause the data to satisfy the set of parity check equations, such as by correcting one or more errors in the data (e.g., a write error, a read error, an error caused by noise, etc.).

The decoding process may continue until the decoding process converges on a valid codeword or until the decoding process reaches a threshold number of iterations (or “times out”). If the decoding process converges on a valid codeword, the codeword may be mapped to user data, and the user data may be sent to the host device 156, as an illustrative example. Thus, the decoding process may be terminated in response to the data converging to a valid codeword. Alternatively, if the decoding process reaches the threshold number of iterations (e.g., due to an error rate of data exceeding an error correction capability associated with the particular ECC scheme), the controller may send an indication to the host device 156 indicating that the data is unavailable, as an illustrative example. In this case, the decoding process is terminated in response to the decoding process iterating a threshold number of iterations (e.g., 10, 15, 20, or another number).

The method 700 may be implemented at one or more decoder devices. In a particular embodiment, the method 700 may be implemented in accordance with a hard-input decoder that is configured to decode hard bits. In this case, the data may include one hard bit per sensed data bit. As an example, the data may include a hard bit corresponding to the value 109. In another example, the method 700 may be implemented in accordance with a decoder that is configured to utilize soft bits. For example, the decoder may be configured to decode soft bits and hard bits. In this case, the data may include one hard bit and one or more soft bits per sensed data bit, such as one hard bit corresponding to the value 109 and one soft bit corresponding to the value 109. As another example, the data may include one hard bit and multiple soft bits per sensed data bit (e.g., one hard bit corresponding to the value 109 and multiple soft bits corresponding to the value 109).

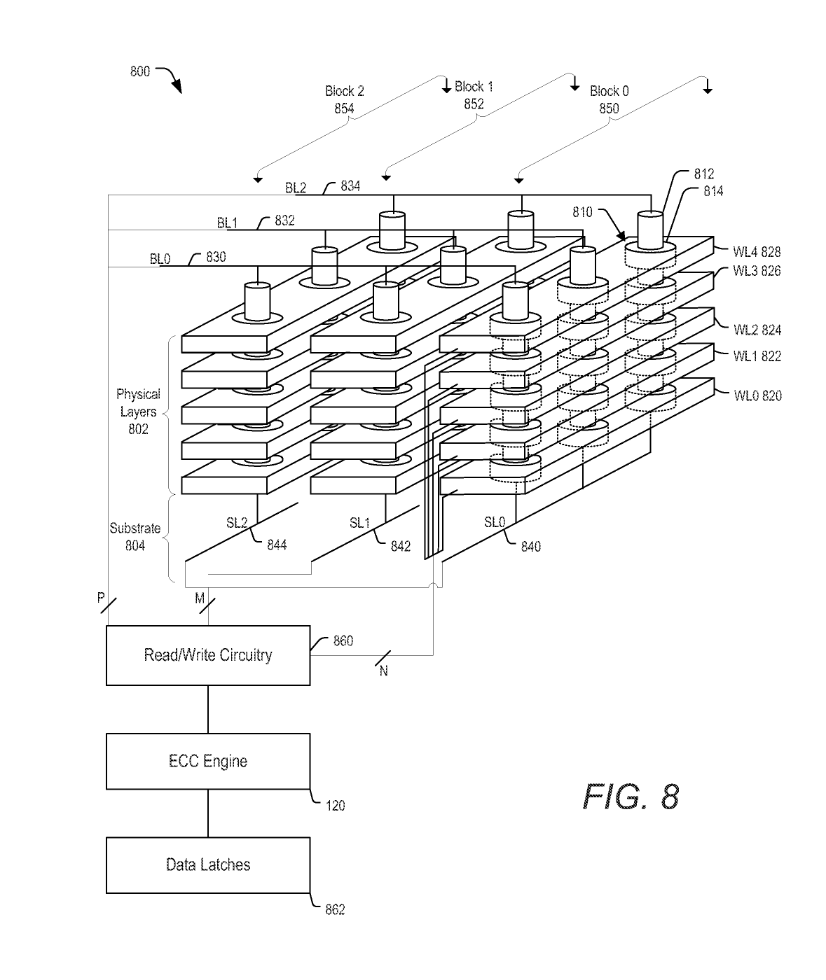

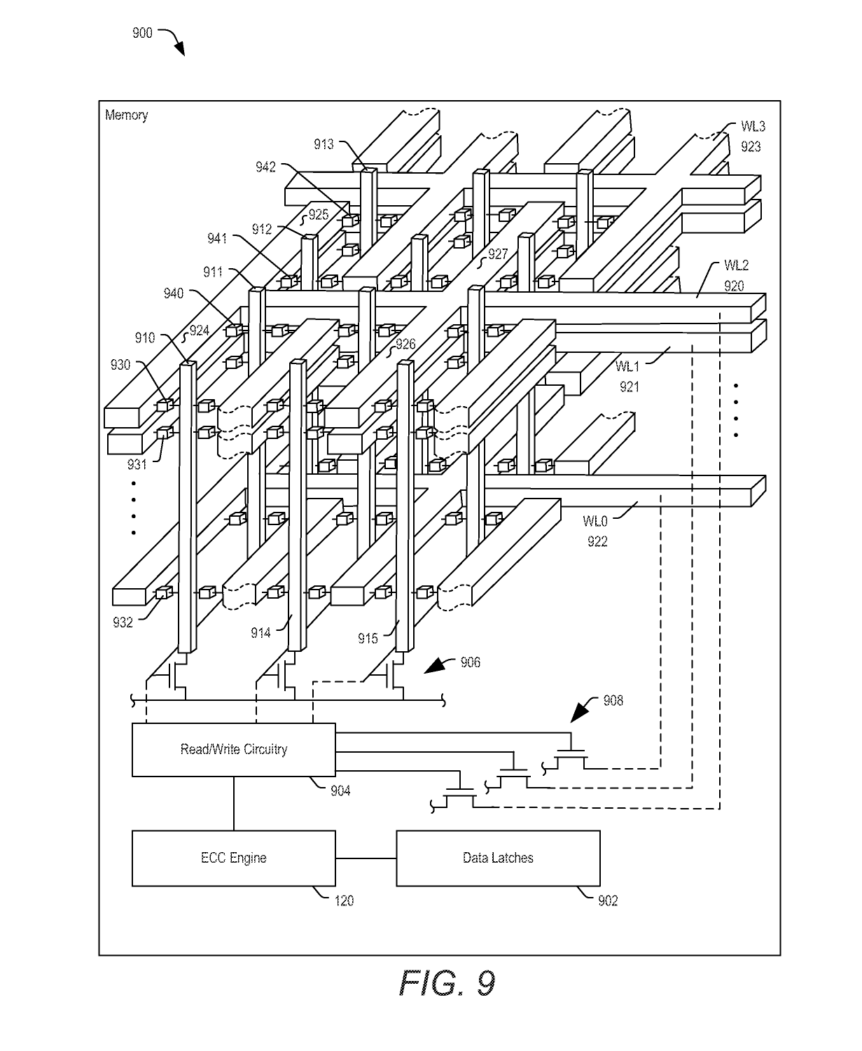

The method 700 may be performed by a decoder that is included in a controller of a data storage device. For example, the method 700 may be performed by the decoder 132 of the controller 110. In another embodiment, the method 700 is performed by a decoder that is included in a memory of a data storage device. For example, the method 700 may be performed by a decoder that is integrated within the memory 104, such as in connection with an “in-memory” ECC implementation. Illustrative in-memory ECC techniques are described further with reference to FIGS. 8-9.

FIG. 8 illustrates an embodiment of a three-dimensional (3D) memory 800 having a NAND flash configuration. The 3D memory 800 may correspond to the memory 104 of FIG. 1. The 3D memory 800 includes multiple physical layers 802 that are monolithically formed above a substrate 804, such as a silicon substrate. Storage elements (e.g., memory cells), such as a representative memory cell 810, are arranged in arrays in the physical layers 802. In addition, the example of FIG. 8 illustrates that the 3D memory 800 may include the ECC engine 120 of FIG. 1 (e.g., in connection with an in-memory ECC implementation). In one or more other implementations, the 3D memory 800 may not include an ECC engine.

The representative memory cell 810 includes a charge trap structure 814 between a word line/control gate (WL4) 828 and a conductive channel 812. Charge may be injected into or drained from the charge trap structure 814 via biasing of the conductive channel 812 relative to the word line 828. For example, the charge trap structure 814 may include silicon nitride and may be separated from the word line 828 and from the conductive channel 812 by a gate dielectric, such as silicon oxide. An amount of charge in the charge trap structure 814 affects an amount of current through the conductive channel 812 during a read operation of the memory cell 810 and indicates one or more bit values that are stored in the memory cell 810.

The 3D memory 800 includes multiple erase blocks, including a first block (block 0) 850, a second block (block 1) 852, and a third block (block 2) 854. Each block 850-854 includes a “vertical slice” of the physical layers 802 that includes a stack of word lines, illustrated as a first word line (WL0) 820, a second word line (WL1) 822, a third word line (WL2) 824, a fourth word line (WL3) 826, and a fifth word line (WL4) 828. Multiple conductive channels (having a substantially vertical orientation (i.e., having an up and down orientation in FIG. 8) that is substantially perpendicular to an upper surface of the substrate 804) extend through the stack of word lines. Each conductive channel is coupled to a storage element in each word line 820-828, forming a NAND string of storage elements. FIG. 8 illustrates three blocks 850-854, five word lines 820-828 in each block, and three conductive channels in each block for clarity of illustration. However, the 3D memory 800 may have more than three blocks, more than five word lines per block, and more than three conductive channels per block.

The 3D memory 800 further includes read/write circuitry 860 and data latches 862. The read/write circuitry 860 may correspond to the read/write circuitry 106 of FIG. 1. The read/write circuitry 860 is coupled to the conductive channels via multiple conductive lines, illustrated as a first bit line (BL0) 830, a second bit line (BL1) 832, and a third bit line (BL2) 834 at a “top” end of the conducive channels (e.g., farther from the substrate 804) and a first source line (SL0) 840, a second source line (SL1) 842, and a third source line (SL2) 844 at a “bottom” end of the conductive channels (e.g., nearer to or within the substrate 804). The read/write circuitry 860 is illustrated as coupled to the bit lines 830-834 via “P” control lines, coupled to the source lines 840-844 via “M” control lines, and coupled to the word lines 820-828 via “N” control lines. Each of P, M, and N has a positive integer value based on the specific configuration of the 3D memory 800. In the illustrative example of FIGS. 8, P=3, M=3, and N=5.

In operation, data may be latched into the data latches 862 (e.g., by the controller 110 of FIG. 1) for writing to one of the word lines 820-828. In the particular example of FIG. 8, the data may be provided from the data latches 862 to the ECC engine 120, and the ECC engine 120 may generate encoded data (e.g., an ECC codeword) based on the data. To write the encoded data to one or more of the word lines 820-828, the read/write circuitry 860 may read bits from an output of the ECC engine 120 and may apply selection signals to control lines coupled to the word lines 820-828, the bit lines 830-834, and the source lines 840-842 to cause a programming voltage (e.g., a voltage pulse or series of voltage pulses) to be applied across selected storage element(s) of the selected word line (e.g., the fourth word line 828).

During a read operation, the controller 110 of FIG. 1 may receive a request from a host device, such as the host device 156 of FIG. 1. The controller 110 may cause the read/write circuitry 860 to read bits from particular storage elements of the 3D memory 800 by applying appropriate signals to the control lines to cause storage elements of a selected word line to be sensed. The logical values read from the storage elements of the selected word line may be provided to the ECC engine 120. The ECC engine 120 may decode the logical values using one or more techniques described herein (e.g., operations of the method 700 of FIG. 7) to generate decoded data. The ECC engine 120 may provide the decoded data to the data latches 862, and the decoded data may be provided from the data latches 862 to the controller 110.

FIG. 9 is a diagram of a particular embodiment of a memory 900. The memory may correspond to the memory 104 of FIG. 1. FIG. 9 illustrates a portion of a three-dimensional architecture of the memory 900 according to a particular embodiment. In the embodiment illustrated in FIG. 9, the memory 900 is a vertical bit line resistive random access memory (ReRAM). In addition, the example of FIG. 9 illustrates that the memory 900 may include the ECC engine 120 of FIG. 1 (e.g., in connection with an in-memory ECC implementation). In one or more other implementations, the memory 900 may not include an ECC engine.

The memory 900 may include a plurality of conductive lines in physical layers over a substrate (e.g., substantially parallel to a surface of the substrate), such as representative word lines 920, 921, 922, and 923 (only a portion of which is shown in FIG. 9). The memory 900 may further include a plurality of vertical conductive lines through the physical layers, such as representative bit lines 910, 911, 912, and 913. The memory 900 also includes a plurality of resistance-based storage elements (e.g., memory cells), such as representative storage elements 930, 931, 932, 940, 941, and 942, each of which is coupled to a bit line and a word line in arrays of memory cells in multiple physical layers over the substrate (e.g., a silicon substrate).

The memory 900 also includes data latches 902 and read/write circuitry 904. In a particular embodiment, the data latches 902 correspond to the data latches 862 of FIG. 8. The read/write circuitry 904 may correspond to the read/write circuitry 106 of FIG. 1 and/or the read/write circuitry 860 of FIG. 8. The read/write circuitry 904 is coupled to word line drivers 908 and bit line drivers 906.

In the embodiment illustrated in FIG. 9, each of the word lines includes a plurality of fingers. For example, a first word line 920 includes fingers 924, 925, 926, and 927. Each finger may be coupled to more than one bit line. To illustrate, a first finger 924 of the first word line 920 is coupled to a first bit line 910 via a first storage element 930 at a first end of the first finger 924 and is coupled to a second bit line 911 via a second storage element 940 at a second end of the first finger 924.

In the embodiment illustrated in FIG. 9, each bit line may be coupled to more than one word line. To illustrate, the first bit line 910 is coupled to the first word line 920 via the first storage element 930 and is coupled to a third word line 922 via a third storage element 932.

During a write operation, the controller 110 may receive data from a host device, such as the host device 156 of FIG. 1. The controller 110 may send the data (or a representation of the data) to the memory 900 to be stored in the data latches 902. The ECC engine 120 may access the data from the data latches 902 and may encode the data (e.g., to generate an ECC codeword).

The read/write circuitry 904 may read bits from an output of the ECC engine 120 and may apply selection signals to selection control lines coupled to the word line drivers 908 and the bit line drivers 906 to cause a write voltage to be applied across a selected storage element. For example, to select the first storage element 930, the read/write circuitry 904 may activate the word line drivers 908 and the bit line drivers 906 to drive a programming current (also referred to as a write current) through the first storage element 930. To illustrate, a first write current may be used to write a first logical value (e.g., a value corresponding to a high-resistance state) to the first storage element 930, and a second write current may be used to write a second logical value (e.g., a value corresponding to a low-resistance state) to the first storage element 930. The programming current may be applied by generating a programming voltage across the first storage element 930 by applying a first voltage to the first bit line 910 and to word lines other than the first word line 920 and applying a second voltage to the first word line 920. In a particular embodiment, the first voltage is applied to other bit lines (e.g., the bit lines 914, 915) to reduce leakage current in the memory 900.

During a read operation, the controller 110 may receive a request from a host device, such as the host device 156 of FIG. 1. The controller 110 may cause the read/write circuitry 904 to read bits from particular storage elements of the memory 104 by applying selection signals to selection control lines coupled to the word line drivers 908 and the bit line drivers 906 to cause a read voltage to be applied across a selected storage element. For example, to select the first storage element 930, the read/write circuitry 904 may activate the word line drivers 908 and the bit line drivers 906 to apply a first voltage (e.g., 0.7 volts (V)) to the first bit line 910 and to word lines other than the first word line 920. A lower voltage (e.g., 0 V) may be applied to the first word line 920. Thus, a read voltage is applied across the first storage element 930, and a read current corresponding to the read voltage may be detected at a sense amplifier of the read/write circuitry 904. The read current corresponds (via Ohm's law) to a resistance state of the first storage element 930, which corresponds to a logical value stored at the first storage element 930.

The logical value read from the first storage element 930 and other elements read during the read operation may be provided to the ECC engine 120 for decoding. The ECC engine 120 may decode the logical values to generate decoded data. The decoded data may be provided from the ECC engine to the data latches 902 and to the controller 110.

Although the ECC engine 120 of FIG. 9 and certain other components described herein are illustrated as block components and described in general terms, such components may include one or more microprocessors, state machines, and/or other circuits configured to enable the data storage device 102 (or one or more components thereof) to perform operations described herein. One or more components described herein may be operationally coupled using one or more nodes, one or more buses (e.g., data buses and/or control buses), one or more other structures, or a combination thereof. One or more components described herein may include one or more physical components, such as hardware controllers, state machines, logic circuits, one or more other structures, or a combination thereof, to enable the data storage device 102 to perform one or more operations described herein. As an illustrative example, the decoder 132 may include a state machine configured to maintain a value indicating a number of decoding iterations performed for a decoding process.

Alternatively or in addition, one or more aspects of the data storage device 102 may be implemented using a microprocessor or microcontroller programmed (e.g., by executing instructions) to perform operations described herein, such as one or more operations of the method 700. Operations illustrated with reference to Examples 2-7 can be implemented at a microprocessor or microcontroller using executable instructions. In a particular embodiment, the data storage device 102 includes a processor executing instructions (e.g., firmware) retrieved from the memory 104. Alternatively or in addition, instructions that are executed by the processor may be retrieved from a separate memory location that is not part of the memory 104, such as at a read-only memory (ROM). One or more operations described herein as being performed by the controller 110 may be performed at the memory 104 (e.g., “in-memory” ECC decoding, as an illustrative example) alternatively or in addition to performing such operations at the controller 110.

To further illustrate, the controller 110 may include a processor that is configured to execute instructions to perform certain operations (e.g., an algorithm) described herein. The instructions may include general purpose instructions, and the processor may include a general purpose execution unit operable to execute general purpose instructions. The processor may access the instructions from the memory 104, the memory 114, another memory location, or a combination thereof. The processor may execute the instructions to initiate a decoding process to decode data sensed from the memory. For example, the processor may execute one or more instructions to input the sensed data 116 to the decoder 132. The processor may execute the instructions to access a mapping table to determine a variable node message value during a variable node processing operation of the decoding process. For example, the VNU processor 500 may execute one or more instructions to access the mapping table 212 to determine the value Q. The variable node message value may be included in a variable node message, and the variable node message may be provided to a check node unit. The check node unit may perform check node processing using the variable node message value and may generate updated check node message values, which may be provided to the VNU processor 500, as an illustrative example. Variable node processing and check node processing may continue until the decoding process converges on a valid ECC codeword or until the decoding process “times out” in response to iterating a threshold number of times. Alternatively or in addition, a processor may execute instructions to perform one or more other operations described herein.

The data storage device 102 may be attached to or embedded within one or more host devices, such as within a housing of a host communication device (e.g., the host device 156). For example, the data storage device 102 may be integrated within an apparatus such as a mobile telephone, a computer (e.g., a laptop, a tablet, or a notebook computer), a music player, a video player, a gaming device or console, an electronic book reader, a personal digital assistant (PDA), a portable navigation device, or other device that uses internal non-volatile memory. However, in other embodiments, the data storage device 102 may be implemented in a portable device configured to be selectively coupled to one or more external devices, such as the host device 156.

To further illustrate, the data storage device 102 may be configured to be coupled to the host device 156 as embedded memory, such as in connection with an embedded MultiMedia Card (eMMC®) (trademark of JEDEC Solid State Technology Association, Arlington, Va.) configuration, as an illustrative example. The data storage device 102 may correspond to an eMMC device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The memory 104 may include a three-dimensional (3D) memory, a flash memory (e.g., a NAND memory, a NOR memory, a single-level cell (SLC) flash memory, a multi-level cell (MLC) flash memory, a divided bit-line NOR (DINOR) memory, an AND memory, a high capacitive coupling ratio (HiCR) device, an asymmetrical contactless transistor (ACT) device, or another flash memory), an erasable programmable read-only memory (EPROM), an electrically-erasable programmable read-only memory (EEPROM), a read-only memory (ROM), a one-time programmable memory (OTP), a resistive random access memory (ReRAM), or a combination thereof. Alternatively or in addition, the memory 104 may include another type of memory. The memory 104 may include a semiconductor memory device.

Semiconductor memory devices include volatile memory devices, such as dynamic random access memory (“DRAM”) or static random access memory (“SRAM”) devices, non-volatile memory devices, such as resistive random access memory (“ReRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles, or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., a NOR memory array. NAND and NOR memory configurations are exemplary, and memory elements may be otherwise configured.

The semiconductor memory elements located within and/or over a substrate may be arranged in two or three dimensions, such as a two dimensional memory structure or a three dimensional memory structure. In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor such as silicon.

The memory elements may be arranged in the single memory device level in an ordered array, such as in a plurality of rows and/or columns. However, the memory elements may be arrayed in non-regular or non-orthogonal configurations. The memory elements may each have two or more electrodes or contact lines, such as bit lines and word lines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate). As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration, e.g., in an x-z plane, resulting in a three dimensional arrangement of memory elements with elements on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device levels. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span through multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Alternatively, two dimensional arrays may be formed separately and then packaged together to form a non-monolithic memory device having multiple layers of memory. For example, non-monolithic stacked memories can be constructed by forming memory levels on separate substrates and then stacking the memory levels atop each other. The substrates may be thinned or removed from the memory device levels before stacking, but as the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

Associated circuitry is typically required for operation of the memory elements and for communication with the memory elements. As non-limiting examples, memory devices may have circuitry used for controlling and driving memory elements to accomplish functions such as programming and reading. This associated circuitry may be on the same substrate as the memory elements and/or on a separate substrate. For example, a controller for memory read-write operations may be located on a separate controller chip and/or on the same substrate as the memory elements.

One of skill in the art will recognize that this invention is not limited to the two dimensional and three dimensional exemplary structures described but cover all relevant memory structures within the spirit and scope of the invention as described herein and as understood by one of skill in the art. The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments. Those of skill in the art will recognize that such modifications are within the scope of the present disclosure.

The above-disclosed subject matter is to be considered illustrative, and not restrictive, and the appended claims are intended to cover all such modifications, enhancements, and other embodiments, that fall within the scope of the present disclosure. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method comprising:
at a data storage device that includes a memory, performing:
initiating a decoding process at the data storage device to decode data sensed from the memory; and
during a variable node processing operation of the decoding process, accessing a mapping table to determine a variable node message value.

2. The method of claim 1, wherein the mapping table is accessed by a variable node unit (VNU) processor using a mapping indicator to select the variable node message value during the variable node processing operation.

3. The method of claim 1, further comprising:
providing a variable node message to a row-wise shifter, wherein the variable node message includes the variable node message value; and
row-shifting the variable node message to generate a row-shifted variable node message.

4. The method of claim 3, further comprising, during a check node processing operation of the decoding process, determining a check node message value using the row-shifted variable node message.

5. The method of claim 4, wherein the variable node processing operation and the check node processing operation include adjusting one or more values of the data based on a set of parity check equations associated with a parity check matrix.

6. The method of claim 5, wherein the decoding process is terminated either in response to the data converging to a valid codeword or in response to the decoding process iterating a threshold number of iterations.

7. The method of claim 1, wherein the data includes one hard bit per sensed data bit.

8. The method of claim 1, wherein the data includes one hard bit and one soft bit per sensed data bit.

9. The method of claim 1, performed by a decoder that is included in a controller of the data storage device.

10. The method of claim 1, performed by a decoder that is included in the memory.

11. The method of claim 1, wherein the memory has a three-dimensional (3D) configuration that is monolithically formed in one or more physical levels of arrays of memory cells having an active area above a silicon substrate, and wherein the memory further includes circuitry associated with operation of the memory cells.

12. A data storage device comprising:
a memory; and
a decoder, wherein the decoder is configured to initiate a decoding process to decode data sensed from the memory, and wherein the decoder is further configured to access a mapping table to determine a variable node message value during a variable node processing operation of the decoding process.

13. The data storage device of claim 12, wherein the decoder includes a variable node unit (VNU) processor, and wherein the mapping table is accessed by the VNU processor using a mapping indicator to select the variable node message value during the variable node processing operation.

14. The data storage device of claim 12, further comprising a row-wise shifter configured to row-shift a variable node message that includes the variable node message value to generate a row-shifted variable node message.

15. The data storage device of claim 14, further comprising a check node unit (CNU) configured to determine a check node message value using the row-shifted variable node message.

16. The data storage device of claim 15, wherein the variable node processing operation and the check node processing operation include adjusting one or more values of the data based on a set of parity check equations associated with a parity check matrix.

17. The data storage device of claim 16, wherein the decoding process is terminated either in response to the data converging to a valid codeword or in response to the decoding process iterating a threshold number of iterations.

18. The data storage device of claim 12, wherein the decoder is included in a controller of the data storage device.

19. The data storage device of claim 12, wherein the decoder is included in the memory, and further comprising a controller that is operationally coupled to the memory.

20. The data storage device of claim 12, wherein the memory has a three-dimensional (3D) configuration that is monolithically formed in one or more physical levels of arrays of memory cells having an active area above a silicon substrate, and further comprising circuitry associated with operation of the memory cells.
